(19) United States
(12) Patent Application Publication
(10) Pub. No.: US 2023/0395560 A1
(43) Pub. Date: Dec. 7, 2023

(54) LOW TEMPERATURE BONDING OF MICRODEVICE INTEGRATION INTO A SYSTEM SUBSTRATE

(71) Applicant: VueReal Inc., Waterloo (CA)

(72) Inventors: Gholamreza CHAJI, Waterloo (CA); Ehsanollah FATHI, Waterloo (CA); Hossein Zamani SIBONI, Waterloo (CA); Lauren LESERGENT, Kitchener (CA); David HWANG, Waterloo (CA); Pranav GAVIRNENI, Waterloo (CA)

(73) Assignee: VueReal Inc., Waterloo, ON (CA)

(21) Appl. No.: 18/043,628

(22) PCT Filed: Sep. 2, 2021
(86) PCT No.: PCT/CA2021/051218

§ 371 Date: Mar. 1, 2023

Related U.S. Application Data
(60) Provisional application No. 63/073,594, filed on Sep. 2, 2020.
(60) Provisional application No. 63/082,574, filed on Sep. 24, 2020.
(60) Provisional application No. 63/110,535, filed on Nov. 6, 2020.

(51) Int. Cl. H01L 23/00

(52) U.S. Cl. CPC H01L 24/80; H01L 2224/80896; H01L 2224/80895

(57) ABSTRACT

This disclosure is related to integrating microdevices into a system substrate. In particular the microdevices are transferred from a donor substrate into a system backplane where the microdevices connection pads are adhered to a pads on the system substrate at a temperature that is below the melting point of the materials on the pads of the system substrate and microdevice pads. The present disclosure also relates to integrating vertical microdevices into a system substrate. The system substrate can have a backplane circuit as well. The integration covers the microdevices with dielectrics and couples the backplane through a VIA. The disclosure further relates to a method and structure of microdevice or optoelectronic devices that allows for misalignment adjustment. The microdevices comprise a stack of semiconductor layers that in configuration with electrodes, substrate, VIA's and size factors minimize misalignment.

### FIELD OF THE INVENTION

The present disclosure relates to the integration of microdevices into a system substrate as well as integrating vertical microdevices into a substrate. The invention further relates to providing misalignment adjustment in microdevices.

### BRIEF SUMMARY

A few embodiments of this description are related to integration of microdevices into the system substrate. The system substrate may comprise micro light emitting diodes (LEDs), Organic LEDs, sensors, solid state devices, integrated circuits, (micro-electro-mechanical systems) MEMS, and/or other electronic components. Other embodiments are related to patterning and placing of microdevices in respect to the pixel arrays to optimize the microdevice utilizations in selective transfer processes. The receiving substrate may be, but is not limited to, a printed circuit board (PCB), thin film transistor backplane, integrated circuit substrate, or, in one case of optical microdevices such as LEDs, a component of a display, for example a driving circuitry backplane. The patterning of microdevice donor substrate and receiver substrate can be used in combination with different transfer technology including but not limited to pick and place with different mechanisms (e.g. electrostatic transfer head, elastomer transfer head), or direct transfer mechanism such as dual function pads and more.

In one embodiment, the invention relates to a bonding process of a microdevice into a system substrate where the system substrate has at least one pad for coupling to a microdevice and part of the pad on the system substrate or microdevice is shielded by a dielectric layer.

In one embodiment the invention relates to providing a method to minimize misalignment defects in microdevices, the method comprising, having a microdevice made of a stack of semiconductor layers, having active layers that are sandwiched between doped layers, coupling doped layers to ohmic layers, coupling the ohmic layers to a first and second electrodes, placing the microdevice on a first substrate, having a first bonding layer between the microdevice and the substrate, forming a planarization layer on the substrate and the microdevice, opening a VIA in the planarization on top of the microdevice; and making a third electrode larger than the VIA.

The present invention relates to a method to integrate vertical microdevices into a system substrate the method comprising, covering a sidewall of a microdevice with a first dielectric, covering a top surface of microdevice with a second dielectric, and creating a first VIA opening on the second dielectrics. The bottom side of the microdevice may be covered by a third dielectric and a second VIA opening is created in the third dielectric.

### BRIEF DESCRIPTION OF THE DRAWINGS

The foregoing and other advantages of the disclosure will become apparent upon reading the following detailed description and upon reference to the drawings.

FIG. 1A shows a donor setup where a donor substrate has microdevices and a housing structure holds the microdevices.

FIG. 1B shows a transferred microdevice into a system substrate.

FIG. 1C shows a microdevice integrated into the system substrate after the curing process.

FIGS. 2A and 2B show a microdevice made of a stack of semiconductor layers.

FIG. 3 shows a microdevice made of a stack of semiconductor layers with an additional VIA.

FIG. 4 shows the integration of vertical microdevices into the system substrate.

The present disclosure is susceptible to various modifications and alternative forms, specific embodiments or implementations as have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

In one embodiment, microdevices are transferred from a donor substrate into a system backplane where the microdevices connection pads are adhered to a pad on the system substrate at a temperature that is below the melting point of the materials on the pads of system substrate and microdevice pads.

In a related embodiment, the system substrate with integrated microdevices is heated to a temperature to form an alloy between the pads material on the system substrate and microdevice connection pads.

In yet another related embodiment, a material is filled around the pads of the microdevice or pads of system substrate prior to the alloying process. The filler materials can be cured first or cured at the same time to eliminate the dispersion/expansion of pad materials during the alloying process and as such eliminates possible shorting between pads or other components.

In another embodiment case, at least part of the pads on system substrate or microdevice is separated from other areas by a shield structure. The fence can be polymer or other types of materials.

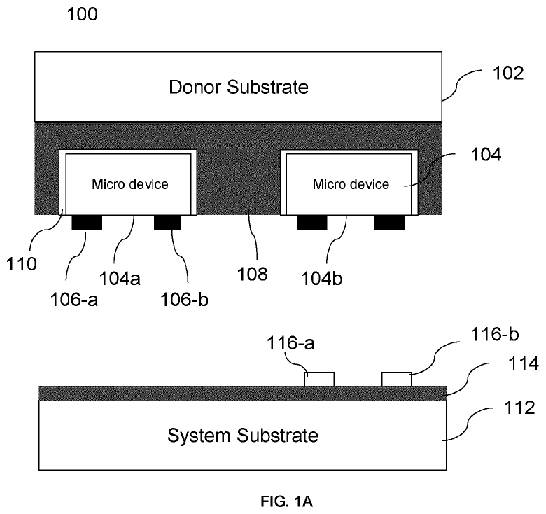

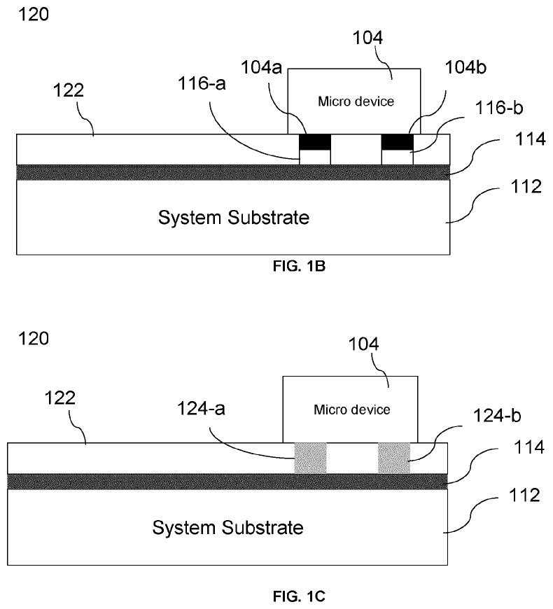

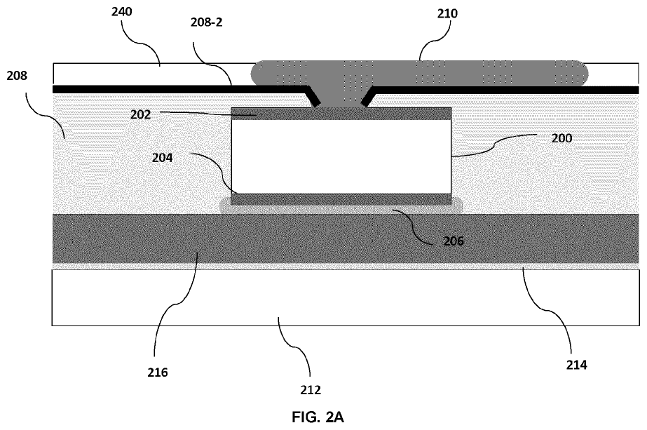

FIG. 1A shows a donor setup 100. The donor substrate 102 can have microdevices 104. In one case, a housing structure 108 can protect and hold the microdevices 104. The microdevices 104 can have connections that are formed as pads 106-a and 106-b. The pads are conductive and may have one or more types of materials. The microdevices 104 can be coupled to the donor substrate 102 directly or through other/extra layers 110. The extra layers 110 can be the release layers. There can be a system substrate 112. The system substrate 112, can include some backplane layers 114 forming either driving circuitry or just connection. Pads 116-a and 116-b can be formed on the substrate 114 that provides connection between backplane layers and to the microdevice 104 after integration. The system substrate pads 116-a and 116-b on the substrate 114 can be composed of a single material or multiple materials (such as Indium, Thin, polymers or In/Au, In/Ag, In/Cu, etc.).

FIG. 1B shows a transferred microdevice 104 into a system substrate 112. the microdevice pads 104-a and 104-b and the system substrates pads 116-a and 116-b are in contact. The contact between microdevice pads and system substrate pads is formed at a temperature below the temperature needed to form an alloy or mixed the pads materials. In some cases, if the system substrate or microdevice pads are heated up at high temperature (melting) and under pressure, the pad area will expand and may cause unwanted shorts. With transferring microdevices at low temperature, this issue is resolved. However, the bonding is not strong enough. In another related case, at least a part of the system substrate or microdevice pads that may expand and cause shorts is also shielded by a layer 122. The shield layer 122 can cover everywhere or a confined area. The shield layer 122 can be formed before the integration of the microdevice 104 into system substrate 112 or after the transfer of the microdevice. The shield layer 122 also can be used as an adhesive layer for integrating microdevices into the system substrate. The setup can be cured at higher temperatures to increase the strength of the bonding. As during this process, no pressure is applied to the microdevices 104, the system substrate pads will not expand. Furthermore, the shield layer 122 can prevent the short. The shield layer 122 can be a polymer or dielectric layer. The shield layer curing can happen at the same time as the pads curing. The shield can be separated from the system substrate pads or connected to them in some areas.

FIG. 1C shows a microdevice 104 integrated into the system substrate 112 after the curing process. As it can be seen, the pads formed one structure 124-a and 124-b.

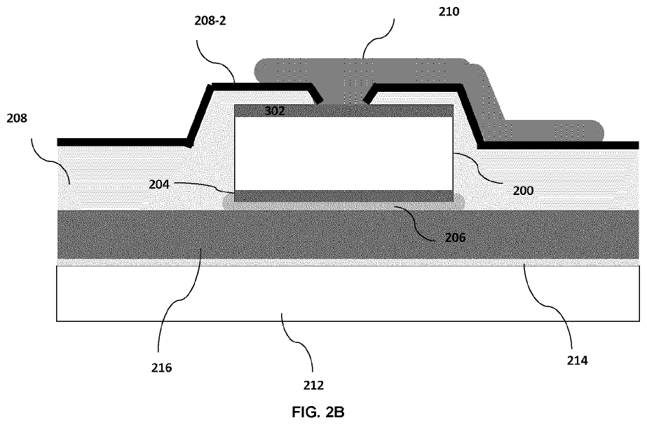

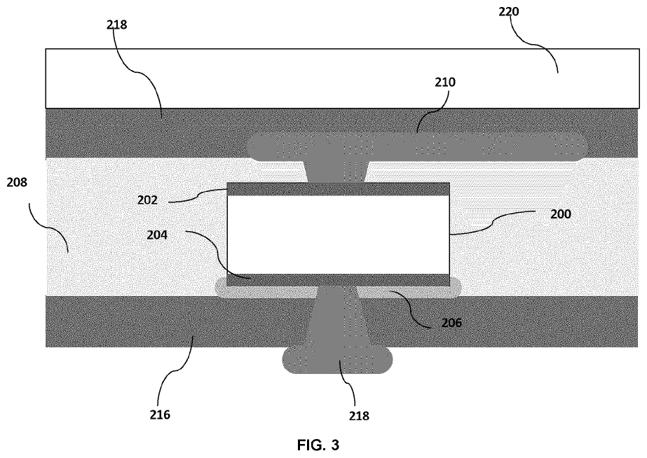

### Embodiments of FIGS. 2 and 3

In this description, the terms “optoelectronic device” and “microdevice” are used interchangeably. However, it is clear to one skilled in the art that the embodiments described here are independent of the device size.

In one embodiment the invention relates to providing a method to minimize misalignment defects in microdevices, the method comprising, having a microdevice made of a stack of semiconductor layers, having active layers that are sandwiched between doped layers, coupling doped layers to ohmic layers, coupling the ohmic layers to a first and second electrodes, placing the microdevice on a first substrate, having a first bonding layer between the microdevice and the substrate, forming a planarization layer on the substrate and the microdevice, opening a VIA in the planarization on top of the microdevice; and making a third electrode larger than the VIA.

In FIGS. 2A and 2B a microdevice 200 (an optoelectronic device made of a stack of semiconductor layers) where active layers are sandwiched between the doped layers and ohmic layers. There can be other electrodes 202, and 204 coupled to the ohmic layers. The ohmic layers can be the same as electrode layers 202, and 204.

In another case, the ohmic layer in the microdevice 200 is smaller than the surface of other layers. Here, the electrodes 202, and 204 are larger than the ohmic layer. There can be a dielectric layer covering the ohmic layer and there is an opening in the dielectric that allows the electrodes 202, and 204 to be coupled to the ohmic layers. The microdevice 200 is placed on a substrate 212. There can be a bonding layer 206 holding the microdevice onto the substrate 212. There can be a buffer/release layer 214 on top of the substrate and another buffer layer 216 on top of the layer 214.

A planarization layer 208 is formed on the substrate 212 and the microdevice 200. A VIA is open in the planarization layer 208 on top of the microdevice 200. The electrode layer 202 is larger than the VIA so that the misalignment is not causing the defect.

The electrode 210 is covering the VIA to couple to the microdevice and connect the microdevice into a signal. The electrode 210 can be transparent to allow the light generated by microdevice 200 to go through the electrode 210.

In one case electrode 210 can be reflective (or opaque). In that case, the electrode 210 can be larger than the microdevice 200 so that it does not light profile of the device 200 due to misalignment between microdevice 200 and the electrode 210. There can be misalignment by placing the microdevice 200 on the substrate 212. There can be misalignment in patterning of the electrode 210. The electrode 210 can be larger than the microdevice at least in one direction and the size difference can be the sum of all misalignments.

The electrode 210 can be part of a backplane 240 that is formed on top of the planarization layer 208. The backplane 240 can include driving circuits for controlling the microdevice 200. The circuits can be made of thin film transistors or CMOS or other types of semiconductors. The backplane may include a dielectric or buffer layer 208-2 separating passivation/planarization layer 208 from the rest of the backplane 240.

In FIG. 3 the microdevice 200 is bonded to another substrate 220 using bonding layer 218. There can be a dielectric layer between the bonding layer 206 and electrode 210. The substrate 212 is removed from the device and other layers. The buffer layer 216 can be removed or left on the structure. A dielectric layer can be deposited on the surface on top of the microdevice or the buffer layer 216.

A VIA through the dielectric layer or the buffer layer 216 is formed to provide access to the electrode 204. The VIA can go through the bonding layer 206, or the bonding layer can be removed. The VIA can be smaller than the 204. The electrode 218 can be transparent to allow the light to pass through. In another case, the electrode 218 can be opaque or reflective. In this case, the electrode 218 can be larger than the device and extended over the edge of the device at least from one point. This allows it to accommodate misalignment without compromising the light profile.

There can be a thick support layer formed on top of the structure in the previous figure before bonding to the second substrate 220. The support layer can be part of the substrate. Or it can be the final substrate after the substrate 220 is removed.

In another case, there can be more than one electrode at the top or bottom of the microdevice, or there can be an electrode at the bottom where the microdevice is bonded to it.

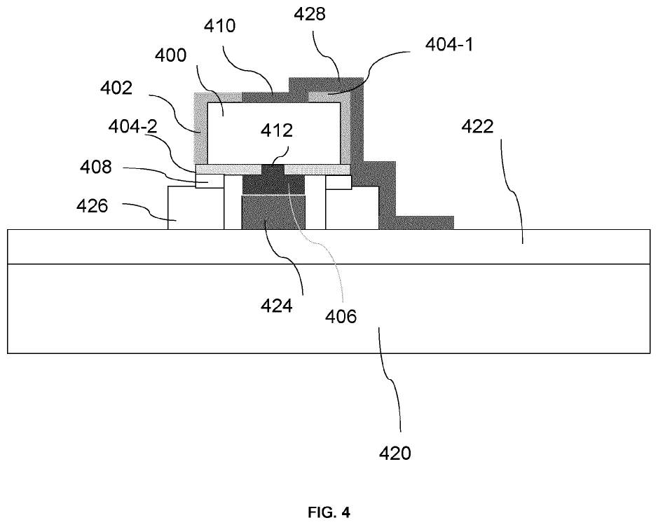

### Embodiments of FIG. 4

Microdevices can be microLED or sensors or MEMS or OLEDs or etc. A system substrate consists of a substrate and a backplane circuitry which controls the microdevices by biasing the microdevices.

This embodiment relates to a method to integrate vertical microdevices into a system substrate the method comprising, covering a sidewall of a microdevice with a first dielectric, covering a top surface of microdevice with a second dielectric, and creating a first VIA opening on the second dielectrics. The bottom side of the microdevice may be covered by a third dielectric and a second VIA opening is created in the third dielectric

The microdevices can be in different forms such as vertical where at least one contact is at the top and one contact is at the bottom surface of the device.

The challenge with vertical microdevice integration into system substrate is the post processing to create contact to the top layer.

FIG. 4 shows an embodiment that simplifies the integration of vertical microdevices into the system substrate. Microdevice 400 can have a dielectric 402 covering the sidewall. Another dielectric 404-1 covering the top surface of the device 400. And there can be another dielectric 404-2 covering the bottom surface of the device 400. The dielectrics 404-1, 404-2, and 402 can be the same layers or different. There is a VIA opening 410 on the top dielectric 404-1. If there is a dielectric 404-2 on the bottom surface of the device, there is a VIA opening 412 in that dielectric 404-2. The dielectric layers can be developed using ALD (Atomic layer deposition), PECVD (Plasma-enhanced chemical vapor deposition), sputtering or other methods. The material used for the dielectric can be organic such as polyamide, BCB (Benzocyclobutene), or inorganic such as SiN, SiO2, etc.

A pad 406 is formed on the bottom surface of the device 400. A dielectric shell 408 can be developed which is surrounding the pads. The dielectric shell 408 can be adhesive.

The system substrate 420 can have backplane circuit 422 on the top surface of the backplane. The backplane circuitry can be coupled to a second pad 424. A second shell 426 is formed to surround the pad 424. The second shell 426 can be adhesive. At least one dimension associated with the area of the shell 426 is larger than the one dimension of the microdevice 400.

The pad 406 of the microdevice 400 is coupled to the pad 424 of the system substrate 120. During the bonding process to couple the pads, the shields 406 and 424 are also bonded protecting the pads such that shields are also bonded to encapsulate the coupled bonds. After this process an electrode 428 can form on top of the device 400 to couple the top side through VIA 410 to the backplane 422. The electrode can be transparent, reflector or opaque.

In one case, it can be patterned in rows or columns. In another related case, it can form a common electrode for a set of microdevices on the system substrate.

The shield can be only on system substrate or microdevice or both. There can be a gap between the pads and shield. In another case, the shield and the pads are connected physically. The combined height of the shields can be the same as the combined height of the pads. If the combined height of either pad or shield is higher than that of the other one, the taller structure needs to be deformed during the bonding to provide coupling of the other structure.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

1. A bonding process of a microdevice into a system substrate where the system substrate has at least one pad for coupling to a microdevice and part of the pad on the system substrate or microdevice is shielded by a dielectric layer.

2. The bonding process of claim 1, wherein the dielectric layer is separated from the pads.

3. The bonding process of claim 1, wherein the dielectric shield is also adhesive.

4. The bonding process of claim 1, the microdevice pads and the system substrates pads are in a contact wherein the contact between microdevice pads and system substrate pads is formed at a temperature below the temperature needed to form an alloy.

5. The bonding process of claim 4, wherein the microdevice pads and the system substrate pads are annealed at higher temperatures after a bonding of the microdevice pads and the system substrates is transferred.

6. The bonding process of claim 1, wherein a housing structure holds the microdevices and microdevices have connections that are formed as microdevice pads.

7. The bonding process of claim 6, wherein the microdevice pads are conductive and are composed of one or more types of material.

8. The bonding process of claim 7, wherein the microdevices are coupled to a donor substrate directly or through release layers.

9. The bonding process of claim 8, wherein the system substrate includes backplane layers forming either a driving circuitry or just a connection.

10. The bonding process of claim 9, wherein the system substrate pads provide connection between backplane layers and to the microdevice after integration.

11. The bonding process of claim 9, wherein the system substrate pads are composed of a single material or multiple materials.

12. The bonding process of claim 1, wherein the system substrate pads are heated up at high temperature and under pressure expanding a system substrate pad area.

13. The bonding process of claim 1, wherein the dielectric layer is formed before the integration of the microdevice.

14. The bonding process of claim 4, wherein the microdevice pads and the system substrate pads become one structure after curing.

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)
